(19) United States
(12) Patent Application Publication
(10) Pub. No.: US 2003/0107379 A1
(43) Pub. Date: Jun. 12, 2003

(54) System and method for monitoring and controlling electrostatic charge

(76) Inventor: Geoffrey M. Weil, Richmond, CA (US)

Correspondence Address: FENWICK & WEST LLP, SILICON VALLEY CENTER, 801 CALIFORNIA STREET, MOUNTAIN VIEW, CA, 94041, US

(21) Appl. No.: 10/015,142

(22) Filed: Dec. 10, 2001

(51) Int. Cl. G01R 29/12

(52) U.S. Cl. 324/458

(57) ABSTRACT

A monitoring system and method detects electrical parameters associated with a conductive strap attached to a user to detect electrical characteristics which may be destructive of sensitive electrical components being manipulated by the user.

### FIELD OF THE INVENTION

This invention pertains to monitoring and controlling electrostatic charge as accumulated, for example, on a worker engaged in fabricating semiconductor devices, and more particularly to a system and a method for verifying that charge-neutralizing measures are operational and effective.

### BACKGROUND OF THE INVENTION

Electrostatic discharge into electronic components has long been known to be a major source of damage in integrated circuits. As devices such as microprocessors become faster, smaller and more complicated, their sensitivity to damage from electrostatic discharges becomes more pronounced. It is important to prevent factory personnel from becoming charged by keeping them grounded. One typical method for doing this is through a grounding wrist strap that typically includes a conductive band of metal, conductive plastic, woven wire, or similar materials which is connected to ground. The connection to ground is normally through a resistor of approximately 1 megohm in series with the wrist strap to prevent the flow of large, potentially dangerous current through the wearer in the case of accidental contact with line voltage.

To be effective, the wrist strap must be periodically tested to insure the integrity of the connection.

Historically, wrist straps made a single connection to the wearer's wrist, and the only way to reliably test the connection was to have the wearer walk to a testing station that measured the resistance of the wrist strap to the skin and through the wearer's finger. Failure limits were within the range of less than 1 megohm, which indicated a short circuit in the safety resistor, to greater than 10 megohms, which indicated a broken connection, or very high skin resistance. (35 meg is the upper limit in some European standards).

This proved unsatisfactory for several reasons including time lost as workers lined up to use the testing station. The test was only effective at the time of the test, and the wrist strap could become defective between tests. There was no way to determine whether the wearer was properly grounded at the work station.

Some attempts to design a continuous monitor to work with a single wire wrist strap proved ineffective. Most attempts were based on a capacitance measurement to determine if the wrist strap was being worn. It was possible to fool such a measurement as with a high resistance connection to the wrist that could still be measured as a valid capacitance. There was no reliable way to measure the resistance through the wrist strap to the skin interface.

One solution to the above problem was to use a split wrist strap that included a band around the wrist divided into two sections, each with its own wire return to a wrist strap monitor which made possible measurements of the actual resistance of the skin to the wrist-strap interface. The monitoring of resistance was continuous so that any failure, even intermittent ones, could be detected. It was also possible to distinguish high resistance and low resistance failures. Certain known wrist strap monitors described below use a split wrist strap.

In addition to the resistance measurement, it is also desirable to measure any voltage present on the wearer. It is possible, by coming into contact with large, ungrounded metal objects such as lamps, and the like, to acquire tens of volts of AC or DC, from a relatively low impedance source. Charging from such a low impedance source is not remediable by a wrist strap, due to the built in 1 megohm resistance, and the small contact area about the wrist. Such voltages are high enough to cause damage in some electronic components.

Among known wrist strap monitors, one product commercially available from 3M Company is understood to apply a constant, relatively high voltage (selectable 9 or 16 volts) through the wearer's wrist to measures resistance by measuring resultant current. The product is not microprocessor controlled and has the disadvantages of applying voltage high enough to cause damage to sensitive devices. (3 volts threshold for giant magneto-restrictive read heads for hard-disk storage devices). In addition, a constant applied voltage prevents making a measurement of the voltage present on the wearer from other sources, such as from contact with charged objects, and the like.

There are reported instances of skin irritation recently from use of this product due, perhaps, to the relatively high, continuous, DC voltage and current applied to the wearer that may be the cause of skin irritation, either through ion pumping through the skin, or by other voltage and/or current driven mechanism.

Another product commercially available from NOVX Company is understood to apply a voltage to the wearer through a resistor network. The wearer becomes part of a voltage divider, and the resultant voltage is detected through a ‘window’ comparator. The main mode of operation is detection of the voltage present on the wearer, but it is also somewhat sensitive to the resistance of the connection to the wearer's skin through the wrist strap. However, it appears that this product cannot make an accurate measurement of the resistance, and has a large indeterminate zone from ten to tens of megohms, and it makes a slow transition from the alarm state into the normal state which makes it difficult to determine whether the wrist strap connection to the wearer is meeting specifications. This product also is understood to apply a varying or constant single polarity voltage to the wearer, as high as 2 volts, and this may lead to irritation, for reasons as described above. Neither side of a split wrist strap connects directly to ground. Any charge drained from the wearer must pass through circuitry of the product, and this has a potential for electrostatic discharge damage since there is not a reliable connection to ground under all operating conditions, including power loss. The product is not microprocessor controlled and must be factory calibrated to meet the desired specifications. Failure thresholds must be set at the factory by a combination of trimpots and jumper plugs.

Another known product that is commercially available from Semtronics Company is understood to apply 5.5V to one side of the wrist strap, and to measure the current through the other side of the strap. This has the disadvantage that the applied DC voltage is still high enough to damage semiconductor devices, and can lead to skin irritation, as described above. The product cannot detect stray voltage on the wearer. And, failure thresholds have to be preset at the factory through selecting resistors and jumper plugs that are not readily field changeable.

Still another known product that is commercially available is a zero-volt monitor, for example, from Semtronics that is believed to place the wearer in a bridge circuit, with one half of the wrist strap being driven positive, and the other half being driven negative. If the wearer presents a balanced resistance from the positive terminal to the negative terminal there will be no voltage at that point. In actuality, any unbalance voltage is believed to be present across the wearer, but it may be possible to find a measurement point that will be at zero volts relative to ground. This product is believed to apply a constant, DC voltage and current to the wearer, and neither side of the wrist strap is believed to be directly connected to ground. There is no reason to assume that the wearer's skin will present identical resistances to both arms of the bridge, due to differences in skin resistance, bulk body resistance, and geometry, and the resulting voltage present at the skin interface may be any value between the positive and negative drive voltages. Also, this product is believed not to be able to detect stray voltages.

### SUMMARY OF THE INVENTION

In accordance with one embodiment of the present invention, one segment of a split wrist strap is connected directly to ground and the resistance of the connection of another segment of the split wrist strap to the wearer's skin is sensed in response to pulses from a constant current source to provide representative voltages over a wide range of skin resistances. Alternate current pulses are applied per measurement cycle to aggregate zero net charge on the wearer. Alternate intervals of each measurement cycle during which the current source is inactive facilitate measurement of voltage on the wearer relative to ground. The test current and voltages to which the wearer is subjected are very low in ranges around about 100 nanoamps and less than 1 volt for resistance values of the connection to the wearer's skin of less than about 10 megohms. All operational parameters including timing of test intervals, failure thresholds, data communications, and the like, are under control of a microprocessor. The parameters are readily programmable both in the field and at the factory to provide selectable operational characteristics and specifications.

### BRIEF DESCRIPTION OF THE DRAWINGS

FIG. 1 shows a schematic circuit diagram of one embodiment of the present invention;

FIGS. 2a-2h are pictorial illustrations of signals in the timing of operations in the circuit of FIG. 1.

FIG. 3 is a flow chart of the monitoring and control process according to our embodiment of the present invention.

### DETAILED DESCRIPTION OF THE INVENTION

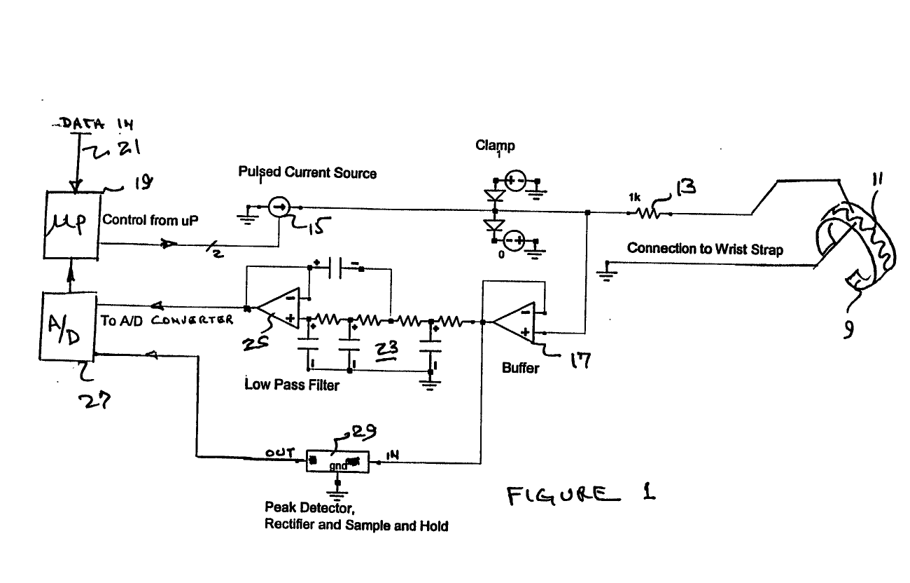

Referring now to FIG. 1, there is shown a conductive element such as a strap 9 that is disposed to be worn on the wrist of a worker while manipulating sensitive electronic components, and that is split into two segments along a longitudinally-oriented boundary. The strap 9 may include suitable fasteners such as Velcro hook-and-loop fabrics positioned along mating ends of the strap in conventional manner to facilitate convenient adjustment and attachment to the wrist of a wearer. The separating border between segments of the wrist strap may be oriented along a serpentine or meandering path to facilitate averaging out variations in skin resistances attributable to differences in moisture and geometric shapes about the wrist of a wearer. Alternatively, the wrist strap 9 may be split into two substantially semicircular segments disposed on opposite crescents of the strap. One segment of the strap 9 is directly connected to ground, and the other segment of the strap 9 is connected through a low-value resistor 13 to the pulsed current source 15, and to the input of buffer amplifier 17. The input to the buffer amplifier 17 is clamped for safety reasons to power supply voltages of about ±5 volts through semiconductor diodes 19, 21 that are connected in conduction opposition in order to limit voltage of either polarity on the strap to not more than the forward-conduction voltage drop (approximately 0.7 volts for semiconductor diodes) above or below the power supply voltages. The pulsed current source 15 of conventional design is controlled in binary manner by microprocessor 19 to deliver approximately 100 nanoamps for a brief interval within recurring test intervals that are each about ½ second in duration during use of the wrist strap 9.

The input to buffer amplifier 17 receives a voltage drop across the wrist strap 9 relative to ground in response to a current pulse from source 15 as an indication of the resistance in the connection of the wrist strap 9 to the wearer's skin. Thus, resistance values of such connection in a range of about 1 to 10 megohms yields voltage drops in the range of only about 100 millivolts to 1 volt for application to the input of buffer amplifier 17. Such voltage drops are insignificantly low to be sensed by the wearer of the wrist strap 9. And, such typical ranges of resistance values in the connection of the wrist strap 9 to the wearer's skin far outweigh the low value of resistor 13 in establishing a test-value of voltage at the input to buffer amplifier 17 that would be indicative of the quality of such connection to the wearer's skin. Resistor 13 is part of the electrostatic discharge protection circuit that helps to prevent circuit damage if the wearer is charged when plugging in the wrist strap 9.

The microprocessor 19 may be programmable in conventional manner via data inputs 21 to control the magnitude and sense or polarity of the current pulses from source 15, the pulse duration, the periodicity of test intervals, test-value limits of tolerable resistance or voltage on the strap 9, and such other parameters as promote versatile test operations.

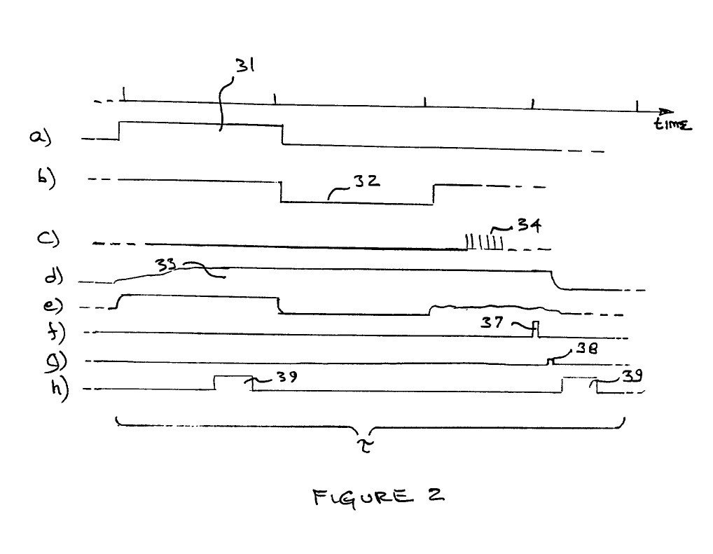

Specifically, in each test interval, as more fully described later herein with reference to FIGS. 2a-2h, the resistance in the connection of the strap 9 to a wearer's wrist may be tested briefly by measuring the voltage appearing on the strap 9 relative to ground in response to an applied current pulse of one polarity or direction from source 15, as previously described. Also, within each test interval, the sense or polarity of the current supplied by source 15 is reversed but the resultant voltage on the strap 9 relative to ground need not be measured to determine the resistance (a non-sign value) in the connection of the strap 9 to the wearer's wrist. The application of a current pulse of opposite sense or polarity during the resistance test integrates to zero the total charge delivered to the wearer during test interval to assure that no residual charge may accumulate on a wearer's body attributable to the resistance test.

Any voltage appearing on the wrist strap 9 attributable to the supplied current pulse as described above, is applied to such monitoring means as amplifier 17 and low-pass filter 23 to exclude line-frequency variations and to select out substantially steady-state voltages and exclude the pulsing rate of voltages appearing on the strap 9. The output of the filter 23 is amplified 25 for application to Analog to Digital Converter 27 as a converter means which produces a digital output indication of the voltage monitored on the wrist strap 9 relative to ground during the time in a test interval that current is supplied from source 15. The output from the A/D converter 27 on the monitored voltage is supplied to a processor means such as microprocessor 19 for analysis of test values within selected alarm limits, for example, of resistance values within a range of 1-10 megohms, or the like, such resistance values may be determined by microprocessor 19 operating in conventional manner to determine the ratio of the voltage appearing on the strap 9 in response to the current of known value supplied thereto.

In addition, within each test interval during an increment in which the source 15 is not active in supplying current, any voltage appearing on the strap 9 attributable to accumulated charge on a wearer's body from such circumstances as previously described may also be measured to provide indication of any electrical conditions that may be destructive of delicate electronic components being manipulated by the wearer of the strap 9.

A measuring means including the sample-and-hold, peak detector 29 operates with a rectifier to receive the output from amplifier 17 for sampling and holding absolute peak voltage values following sampling intervals that are synchronized to inactivity of source 15. Thus, the sample and hold circuit 29 is synchronized for operation in other increments of each test interval during which source 15 does not supply a current pulse for the purpose of testing any residual voltage on the wearer relative to ground caused by other environmental factors. The output of the sample and hold circuit 29 is thus a steady voltage (during its hold phase of operation prior to being reset for subsequent signal sampling) that is supplied to the A/D converter 27 for digitization of the peak, absolute value of output signal from amplifier 17. Numerous samples may be taken and the peak values averaged within each test interval to minimize the effects of random noise perturbations. In this way, time-varying changes of conditions such as appearing on the strap 9 relative to ground can be detected during each test interval, to be analysed by the microprocessor 19 for any trends toward conditions (e.g. too high voltage on the wearer's body) that may be destructive to delicate electronic components. The output of sample and hold circuit 29 thus provides indication of voltage appearing on the strap 9 relative to ground from environmental sources affecting the wearer, and such voltage is digitized by a converter means such as A/D converter 27 for analysis by the microprocessor 19 of any trend of accumulating charge on a wearer's body (and hence voltage on strap 9). Thus, in each test interval of, for example, ½ second duration, the sample and hold circuit 29 may take multiple samples and hold and reset, all at synchronized times relative to source 15 not supplying current pulses. This facilitates testing of different conditions regarding the strap 9 on a wearer's wrist at such synchronized times in each test interval. And, the positive and negative current pulses supplied during different increments of each test interval substantially assure neutralization of ion pumping through a wearer's skin, and assure no residual voltage on the wearer attributable to operation of the present invention in testing voltages on the strap 9 in each test interval. Measurements of the resistance in the connection of the strap 9 to the wearer's skin need only be performed, however, during either one of the intervals of positive and negative current pulses from source 15.

Referring now to FIGS. 2a-2h, there are shown pictorial illustrations of representative signals in the synchronized timing operations of the circuit of FIG. 1. Specifically, the source 15 supplies a current pulse of positive polarity for about 150 milliseconds in response to a control signal 31 from microprocessor 19, as shown in FIG. 2a. The supplied current produces a voltage across strap 9 relative to ground that is applied through amplifier 17 to low-pass filter 23. The output 33 of the filter 23 attains steady state output level, as shown in FIG. 2d, after about 120 milliseconds of the applied positive current pulse 31 for accurate A/D conversion at that time by converter 27. The output of amplifier 17 may be sampled multiple times 34 in each measurement cycle, as shown in FIG. 2C, (for averaging the sampled values in each measurement cycle to reduce the effect of random noise). No samples need be taken during supply of the negative current pulse in response to control signal 32 since the negative current pulse is primarily supplied to neutralize accumulated charge on the wearer's body attributable to the supplied positive current pulse. Voltage variations appearing on the wrist strap 9 relative to ground over a test interval may resemble FIG. 2e. In approximately the last 200 milliseconds of each test interval, the peak detector 29 operates 37 to hold the higher absolute value of sampled voltage excursions from the output of buffer amplifier 17 for digitization 39 by the A/D converter 27. The sample and hold circuit 29 may be reset 38 following transfer of the sampled, held voltage value to the A/D converter 27.

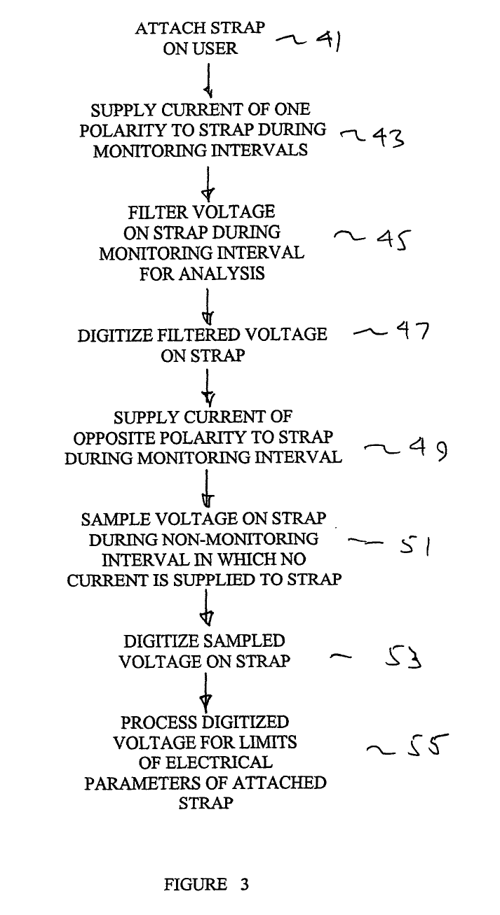

Referring now to the flow chart of FIG. 3, operation of the present invention proceeds from attaching 41 the conductive strap 9 to a user's wrist to form an electrically conductive connection to the user's body. The current source 15 supplies D.C. current of known magnitude and of one polarity (or direction) 43 to the strap 9 for a brief monitoring interval under control of the microprocessor 19. The resultant voltage appearing on the strap 9 attributable to the voltage drop across the resistance of the connection of the strap 9 to the user's wrist is buffered 17 and filtered 45 and digitized 47 for processor-controlled analysis of the resistance value as the ratio of the resultant voltage to the supplied current. A current pulse of opposite polarity (or direction) is supplied 49 to the strap for a period and with a magnitude sufficient to neutralize the charge delivered to the strap 9 during the initial cycle of current of the one polarity (or direction) supplied to the strap 9. In the absence of current supplied to the strap 9 during a non-monitoring interval of a monitoring cycle of operation, voltage appearing on the strap 9 attributable to charge on the user's body, or otherwise attributable to environmental factors, is detected by sampling the voltage 51 for digitization 53 and processor analysis 55. Specifically, the ratio of voltage appearing on the strap 9 in response to the supply of current thereto of known amplitude may be determined in conventional manner by the microprocessor 19 during the monitoring interval, and voltage appearing on the strap 9 during a non-monitoring interval (i.e. no current supplied to the strap 9) may be analysed by the microprocessor 19 operating in conventional manner to identify alarm conditions of high resistance or high voltage on the strap 9. Such monitoring cycles may recur periodically, for example, at ½ second intervals for substantially continuous monitoring of electrical parameters associated with conductive strap 9 attached to a user's wrist.

Therefore, the apparatus and method of the present invention monitors a user for potentially damaging electrical conditions while the user is engaged in manipulating charge-sensitive delicate semiconductor devices. Such monitoring detects accumulated charge and resultant voltage on the user's body, and also detects the adequacy of the conductive connection to the user of the monitoring circuitry including the conductive strap.

What is claimed is:

1. Monitoring apparatus for sensing electrical parameters relative to a conductive element attached to a user, the apparatus comprising:
a source of current connected in electrical communication with the conductive element for supplying current thereto during selected monitoring intervals;
a monitoring circuit connected to receive voltage appearing on the conductive element for producing an output representative of the voltage appearing on the conductive element during supply of current thereto;
a measuring circuit operated in synchronism with the selected monitoring intervals to producing an output indicative of the peak of said voltage on the conductive element during an interval in which current is not supplied to the conductive element; and
a converter circuit connected to the monitoring circuit and to the measuring circuit for producing digital outputs representative of voltages on the conductive element during intervals in which current is supplied and not supplied to the conductive element.

2. Monitoring apparatus as in claim 1 in which the measuring circuit includes a sampler operable during an interval in which current is not supplied to the conductive element for producing said output in response to a number of samples of a voltage indicative of said voltage on the conductive element.

3. Monitoring apparatus as in claim 2 in which the sampler produces a plural number of said samples for generating said output therefrom representative of a logical combination of the plural number of samples.

4. Monitoring apparatus as in claim 1 including a processor in communication with the converter circuit for analysing the digital outputs therefrom to produce an alarm indication in response to an electrical parameter of the conductive element attached to a user exceeding a selected limit.

5. Monitoring apparatus as in claim 4 in which the processor produces said alarm indication in response to a determination from supplied current and resultant voltage across the resistance of the attachment to the user of the conductive element exceeding a selected limit during a monitoring interval.

6. Monitoring apparatus as in claim 4 in which the processor produces said alarm indication in response to voltage on the conductive element attached to the user exceeding a selected limit during the interval that current is not supplied to the conductive element.

7. Monitoring apparatus for sensing electrical parameters relative to a conductive element attached to a user, the apparatus comprising:
source means for supplying current to the conductive element during recurring monitoring intervals;
monitoring means for producing an output representative of voltage appearing on the conductive element during monitoring intervals;
measuring means for producing an output indicative of a peak voltage on the conductive element during non-monitoring intervals; and
converter means operable with the monitoring means and measuring means for producing an output indicative of voltages appearing on the conductive element during monitoring and non-monitoring intervals.

8. Monitoring apparatus as in claim 7 in which the monitoring means includes sampling means for producing said output in response to a number of samples of a signal representative of the voltage on the conductive element during non-monitoring intervals.

9. Monitoring apparatus as in claim 8 in which the sampling means produces said output in response to a logical combination of a plurality of samples of said signal.

10. Monitoring apparatus as in claim 7 including processor means operable with the monitoring means and the measuring means for producing an output indication of an electrical parameter of the attachment to the user of the conductive element exceeding a selected limit.

11. Monitoring apparatus as in claim 10 in which the processor means produces said output indication in response to determination from the supplied current and the resultant voltage on the conductive element during a monitoring interval of the resistance of the attachment to the user exceeding a selected limit.

12. Monitoring apparatus as in claim 10 in which the processor means produces said output indication in response to voltage on the conductive element during a non-monitoring interval exceeding a selected limit.

13. A method for sensing electrical parameters relative to a conductive element attached to a user, comprising:
selectively supplying current to the conductive element during recurring monitoring intervals;
sensing voltage appearing on the conductive element during supply of current thereto; and
sensing voltage appearing on the conductive element in a non-monitoring interval during which current is not supplied to the conductive element.

14. The method of claim 13 including:
producing an output indication in response to the ratio of voltage appearing on the conductive element to the current supplied thereto during a monitoring interval exceeding a selected limit.

15. The method of claim 13 including:
producing an output indication in response to voltage appearing on the conductive element during a non-monitoring interval exceeding a selected limit.

16. The method of claim 13 in which sensing voltage appearing on the conductive element in a non-monitoring interval includes sampling the voltage a number of times in a non-monitoring interval to produce an output signal as a logical combination of the number of samples.

17. The method of claim 16 in which said voltage is sampled a plural number of times in a non-monitoring interval; and
said output signal is produced as an average value of peak sample amplitudes of said voltage.
